(19) United States
(12) Patent Application Publication
(10) Pub. No.: US 2005/0227401 A1
(43) Pub. Date: Oct. 13, 2005

(54) Method of packaging MEMS device in vacuum state and MEMS device vacuum-packaged using the same

(76) Inventors: Ho-Young Lee, Seoul (KR); Yong-Hyup Kim, Yonggin-si (KR); Woo-Yong Sung, Seoul (KR); Wal-Jun Kim, Seoul (KR); Soon-Chang Yeon, Seoul (KR)

Correspondence Address: GLENN PATENT GROUP, 3475 EDISON WAY, SUITE L, MENLO PARK, CA, 94025, US

(21) Appl. No.: 11/070,948

(22) Filed: Mar. 2, 2005

(30) Foreign Application Priority Data
Apr. 13, 2004 (KR) 10-2004-0025198

(51) Int. Cl. H01L 21/00

(52) U.S. Cl. 438/51

(57) ABSTRACT

Provided are a method of packaging an MEMS device in vacuum using an O-ring and a vacuum-packaged MEMS device manufactured by the same. The method includes preparing an upper substrate including a cavity and a lower substrate including the MEMS device and loading the upper and lower substrates into a vacuum chamber; aligning the lower and upper substrates by mounting an O-ring on a marginal portion of the MEMS device of the lower substrate; compressing the O-ring between the upper and lower substrates by applying a pressure between the upper and lower substrates; venting the vacuum chamber; and removing the pressure applied between the upper and lower substrates. In this method, the MEMS device can be packaged in vacuum using a simple process without causing outgassing and leakage from a cavity of the upper substrate.

This application claims the priority of Korean Patent Application No. 2004-25198, filed on Apr. 13, 2004, in the Korean Intellectual Property Office, the disclosure of which is incorporated herein by reference in their entirety.

### BACKGROUND OF THE INVENTION

1. Field of the Invention

The present invention relates to a method of packaging a micro electro mechanical systems (MEMS) device in a vacuum state and a MEMS device manufactured by the same, and more particularly, to a method of packaging an MEMS device in a vacuum state using an O-ring and an MEMS device manufactured by the same.

2. Description of the Related Art

In recent years, MEMS have been proposed as leading, innovative system miniaturization technology in the next generation field of electronic components. For example, various MEMS products, such as an accelerometer, a pressure sensor, an inkjet head, and a hard disc head, are being commonly used throughout the world. Also, micro gyroscopes have been produced in large quantities after the production of first micro gyroscopes was launched upon. Nowadays, with development in optical communications technology, various efficient components for wavelength division multiplexing (WDM) optical communications, such as switches, attenuators, filters, and OXC switches, are being studied as a new challenging field of MEMS technology.

A representative product that derives from MEMS technology is an MEMS gyroscope sensor. A silicon oscillatory gyroscope operates on the principle that when a structure is oscillated in a certain direction due to an electrostatic force and an angular rotation (or an angular velocity) to be detected is given, a Coriolis force acts at a right angle to the oscillation of the structure. At this time, an oscillation acted by the Coriolis force and the extent of an externally applied angular rotation are measured using a variation in capacitance between an inertial body and an electrode.

Micro gyroscopes can be applied in various fields of subminiature low-price global position systems (GPS), inertial navigation systems (INS), automobile industries including vehicle positive control and driving safety devices such as positive suspension systems, household appliances including a virtual reality, 3-dimensional mouse and a hand trembling preventing device for cameras, military applications including generation weapon systems, missile guidance systems, and intelligent ammunition systems, and other industries including machine control, oscillation control, and robotics.

In order to improve the sensitivity of an oscillatory gyroscope, it is necessary that an oscillation frequency obtained in a given direction correspond to that obtained in a measured direction and damping be small. That is, when a structure operates, the structure runs into resistance due to a damping effect caused by air flow and viscosity around the structure, or an air attenuation effect, and a value Q (or a quality factor) decreases. For this reason, the structure need to be operated in a vacuum state and packaged in high vacuum.

FIG. 1 is a cross-sectional view of a conventional oscillatory MEMS gyroscope sensor.

Referring to FIG. 1, the MEMS gyroscope sensor is manufactured using a silicon on insulator (SOI) wafer including a first silicon layer 1, an oxide layer 5, and a second silicon layer 10, which are sequentially stacked. The SOI wafer has a thickness of about 500 μm, and the oxide layer 5 as an insulator has a thickness of about 3 μm. The second silicon layer 10 stacked on the oxide layer 5 is p-type <100> and has a thickness of 40 μm and a resistivity of about 0.01 to 0.02 Ω·cm. The SOI wafer is primarily cleaned, and then a gyroscope structure pattern is formed using a photo-resistor. The resultant structure is sufficiently baked such that the photo-resistor is not carbonized. Thereafter, the second silicon layer 10, the oxide layer 5, and the first oxide layer 5 as a sacrificial layer are sequentially and vertically etched using inductively coupled plasma-reactive ion beam etch (ICP-RIE). The photo-resistor is removed using a dry ashing apparatus, and the resultant structure is dipped in an HF solution such that a gyroscope structure 20 is completely released.

In order to package a lower substrate 25 including the gyroscope structure 20, an upper substrate 30 is prepared. The upper substrate 30 is formed of Corning Pyrex 7740 glass, whose coefficient of thermal expansion is relatively close to that of silicon, and has a thickness of about 350 μm. The glass upper substrate 30 has a cavity 35 inside and a via hole 37 in a top surface as shown in FIG. 1. The cavity 35 is required to protect the gyroscope structure 20 and create a vacuum state. The via hole 37 serves as a path for connecting the gyroscope structure 20 and an external electrical interconnection. The cavity 35 and the via hole 37 of the glass upper substrate 30 are formed using sandblasting.

The lower substrate 25 including the gyroscope structure 20 and the upper substrate 35 including the cavity 35 are aligned and loaded into a vacuum chamber. The degree of vacuum in the chamber is set to about 5×10⁻⁵ Torr, and then anodic bonding is carried out. During the anodic bonding, a voltage is applied to the upper and lower substrates 35 and 25 while raising the temperature of the chamber. After the anodic boding is finished, the upper and lower substrates 35 and 25 are unloaded from the chamber, and an electrical interconnection 40 is formed by depositing Al on the glass upper substrate 35. After that, the bonded upper and lower substrate 35 and 25 are diced into individual chips.

In the foregoing wafer-level vacuum packaging process, the conventional MEMS gyroscope sensor is completed. However, in this case, a variation in degree of vacuum of a package affected by environmental conditions and time is not sufficiently reliable.

When a gyroscope is used, a value Q is varied. If a value Q or a frequency varies, sensitivity and precision, which are performance factors of the gyroscope, are directly affected. When a gyroscope is used, a reduction in value Q means a variation in degree of vacuum of a gyroscope package. In other words, a pressure in a cavity is increased than an initial pressure so that damping of air increases, thus lowering the value Q.

Generally, the rise in the pressure of the cavity results from outgassing or leakage, which occurs in the cavity.

The leakage is caused by holes or micro cracks formed in an interfacial surface between bonded substrates or defects of materials after a bonding process is finished.

The outgassing refers to emission of gases from a cavity during or after a bonding process. During the bonding process, if a high voltage is applied, not only oxygen ions emitted from a glass substrate or an interface between bonded substrates, but also gases contained in contaminants remaining on an inner surface of a package or on the surfaces of materials are continuously outgassed into the cavity with a rise in temperature.

By analyzing outgassing resulting from an SOI wafer and a glass wafer, it can be seen that gases emitted from the wafers contain H₂O for the most part, CO₂, C₃H₅, and other contaminants. Because the glass wafer emits an about 10-fold larger amount of gas than the SOI wafer, the glass wafer becomes a major cause for the outgassing from a cavity. A very large amount of H₂O is outgassed from the glass wafer. Particularly, it is demonstrated that after the glass wafer is processed using sandblasting, an about 2.5-fold larger amount of gas is outgassed than before.

Accordingly, a new method of packaging an MEMS device in vacuum, which solves leakage and outgassing, is required.

### SUMMARY OF THE INVENTION

The present invention provides a method of packaging a micro electro mechanical systems (MEMS) device in vacuum without causing gas leakage and a vacuum-packaged MEMS device manufactured by the same.

Also, the present invention provides a method of packaging an MEMS device in vacuum, which includes neither a baking process nor anodic bonding so that no outgassing occurs, and a vacuum-packaged MEMS device manufactured by the same.

According to an aspect of the present invention, there is provided a method of packaging an MEMS device in vacuum. In this method, an upper substrate including a cavity and a lower substrate including the MEMS device are prepared and loaded into a vacuum chamber. The lower and upper substrates are aligned by mounting an O-ring on a marginal portion of the MEMS device of the lower substrate. The O-ring is compressed between the upper and lower substrates by applying a pressure between the upper and lower substrates. Thereafter, the vacuum chamber is vented so that the upper and lower substrates can be packaged in vacuum due to a difference between vacuum and atmospheric pressure. After that, the pressure applied between the upper and lower substrates is removed.

A sealant, such as a torr-seal, may be filled between the upper and lower substrates outside the O-ring. In order to maintain airtightness, outer portions of the upper and lower substrates may be clamped using a clamp.

After the MEMS device is packaged using wafer-level vacuum packaging, the upper and lower substrates may be diced into individual chips. Also, the upper and lower substrates between which the MEMS device is embedded may be connected by an electrical connection and molded using a molding compound. The molding compound may be formed of one selected from the group consisting of metals, ceramics, glass, and thermosetting resins.

The MEMS device may be one selected from the group consisting of a gyroscope, an accelerator, an optical switch, an RF switch, and a pressure sensor and be used for a system on a package (SoP).

According to another aspect of the present invention, there is provided a vacuum-packaged MEMS device including an upper substrate including an MEMS device; a lower substrate including a cavity; and an elastic O-ring interposed between marginal portions of the upper and lower substrates.

The vacuum-packaged MEMS device may further include a sealant, such as a torr-seal, filled between the upper and lower substrate outside the O-ring. Also, a molding compound may be molded outside the upper and lower substrates between which the MEMS device is embedded. The molding compound may be one of metals, ceramics, glass, and thermosetting resins.

### BRIEF DESCRIPTION OF THE DRAWINGS

The above object and advantages of the present invention will become more apparent by describing in detail exemplary embodiments thereof with reference to the attached drawings in which:

FIG. 1 is a cross-sectional view of a conventional oscillatory micro electro mechanical systems (MEMS) gyroscope sensor;

FIG. 2 is a cross-sectional view of an MEMS gyroscope vacuum-packaged according to an embodiment of the present invention;

FIGS. 3A through 6A are perspective views illustrating a method of packaging an MEMS device according to an embodiment of the present invention;

FIGS. 3B through 6B are cross-sectional views illustrating the method of packaging an MEMS device shown in FIGS. 3A through 6A; and

FIG. 7 is a perspective view illustrating a method of packaging a plurality of MEMS devices in a vacuum state on a wafer level according to another embodiment of the present invention.

### DETAILED DESCRIPTION OF THE INVENTION

The present invention will now be described more fully with reference to the accompanying drawings, in which exemplary embodiments of the invention are shown. In the drawings, the thicknesses of layers or regions may be exaggerated for clarity. The same reference numerals are used to denote the same elements throughout the specification.

In the embodiments of the present invention, an upper substrate including a cavity and a lower substrate including a micro electro mechanical systems (MEMS) device are bonded using an O-ring. Specifically, the upper and lower substrates are spaced a predetermined distance apart from each other by the O-ring in a vacuum chamber and compressed. Then, the vacuum chamber is vented so that the upper and lower substrates can be bonded due to a difference between vacuum and atmospheric pressure. In this process, conventional anodic bonding is not required. Therefore, no outgassing occurs, a process is simple and economical, and no leakage occurs so that high vacuum can be maintained.

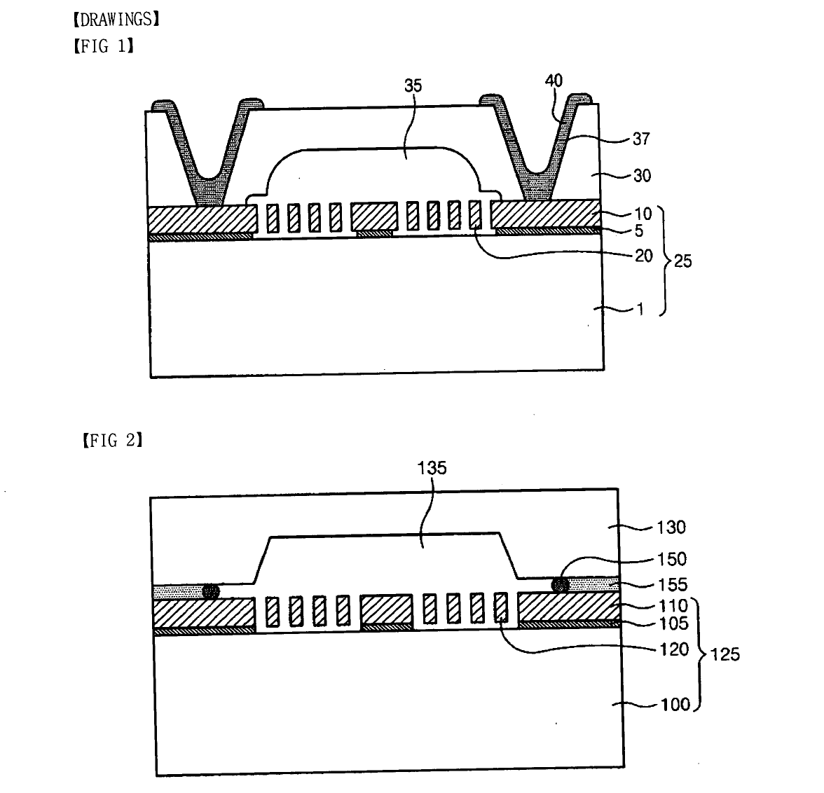

FIG. 2 is a cross-sectional view of an MEMS gyroscope vacuum-packaged according to an embodiment of the present invention.

Referring to FIG. 2, a gyroscope structure 120 is formed by an ordinary method in a silicon on insulator (SOI) lower wafer 125 including a first silicon layer 100, an oxide layer 105, and a second silicon layer 110, which are sequentially stacked. On the lower wafer 125 in which the gyroscope structure 120 is formed, an upper wafer 130 is packaged in vacuum by interposing an O-ring 150. Preferably, the upper wafer 130 includes a cavity 135 inside, and a sealant 155, such as a torr-seal, is filled outside the O-ring 150 interposed between the upper and lower wafers 125 and 130.

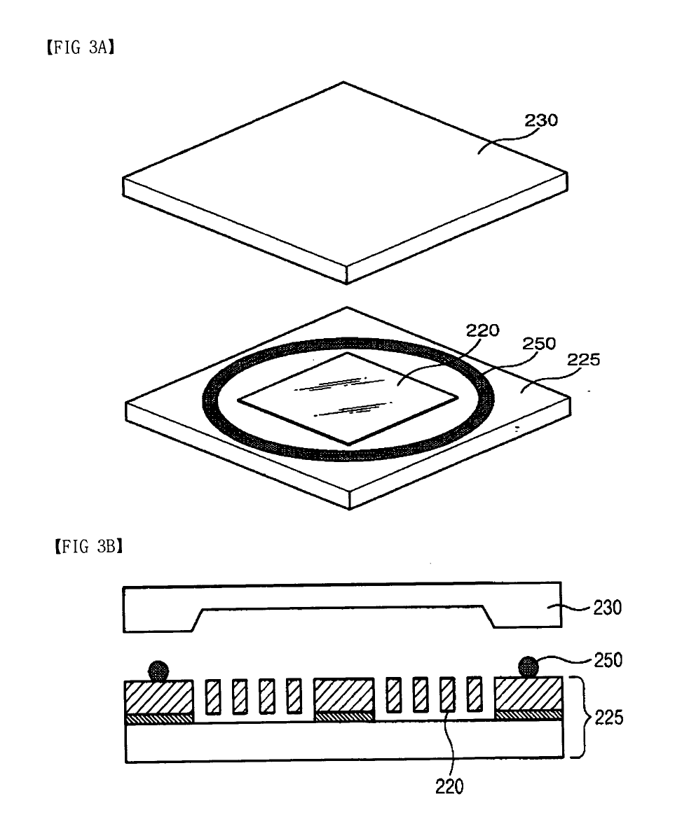

FIGS. 3A through 6A are perspective views illustrating a method of packaging a MEMS device according to an embodiment of the present invention, and FIGS. 3B through 6B are cross-sectional views illustrating the method of packaging an MEMS device shown in FIGS. 3A through 6A. In the embodiments of the present invention, a variety of MEMS devices, for example, a gyroscope, an accelerator, a pressure sensor, an optical switch, and a radio-frequency (RF) switch, can be packaged in vacuum. Preferably, an oscillatory MEMS device can be packaged in vacuum.

Referring to FIGS. 3A and 3B, a lower substrate 225 including an MEMS device 220 and an upper substrate 230 including a cavity are prepared. The upper substrate 230 may be formed of silicon, and the cavity can be formed by performing wet or dry etching using ordinary photolithography.

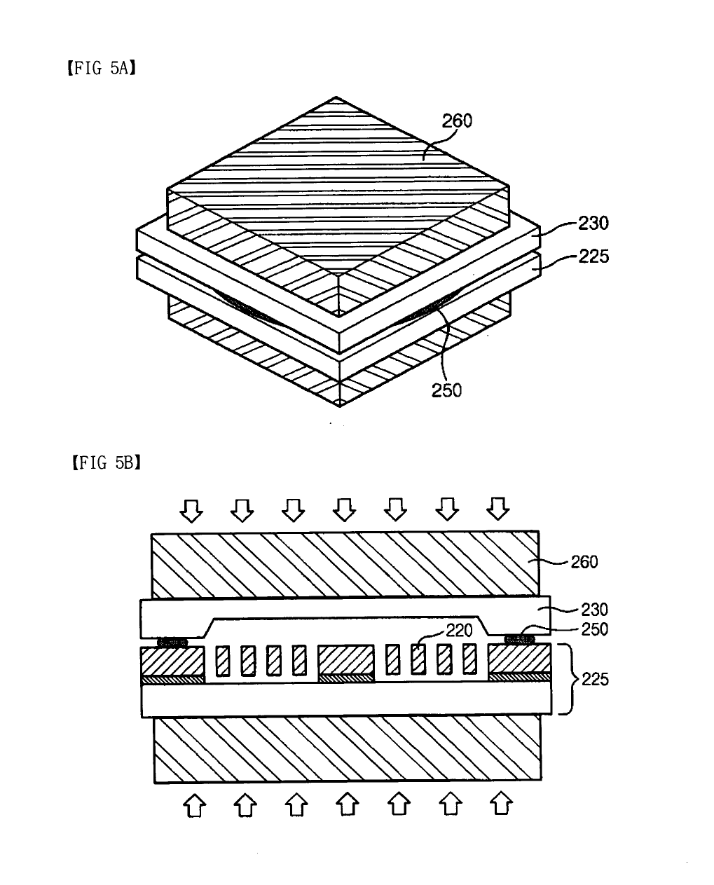

Thereafter, the lower and upper substrates 225 and 230 are loaded into a vacuum chamber (not shown). In order to secure an ultrahigh vacuum state, an exhausting process is performed by operating a pump installed in the chamber. In the vacuum chamber, a pressurizing unit including a pressurizing plate (260 of FIGS. 5A and 5B) is installed to enable high-vacuum exhaust and pressurize the upper and lower substrates 230 and 225.

Thereafter, an O-ring 250 is mounted on the lower substrate 225 such that the MEMS device 220 is surrounded by the O-ring 250. The O-ring 250 may be formed of one of various elastic materials and preprocessed at a temperature of about 230° C. before being put on the lower substrate 225.

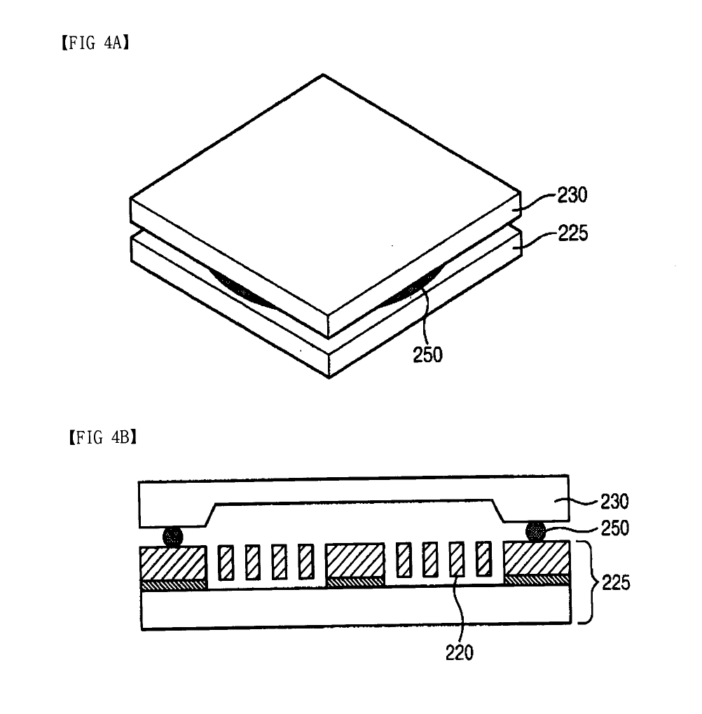

Referring to FIGS. 4A and 4B, the upper substrate 230 is aligned on the lower substrate 225 on which the O-ring 250 is located.

Referring to FIGS. 5A and 5B, the lower and upper substrates 225 and 230 are compressed in a vacuum state by use of the pressurizing plate 260 of the pressurizing unit. Once the upper and lower substrates 225 and 230 are compressed, the O-ring 250, which is elastic, is compressed and closely adhered to the upper and lower substrates 230 and 225.

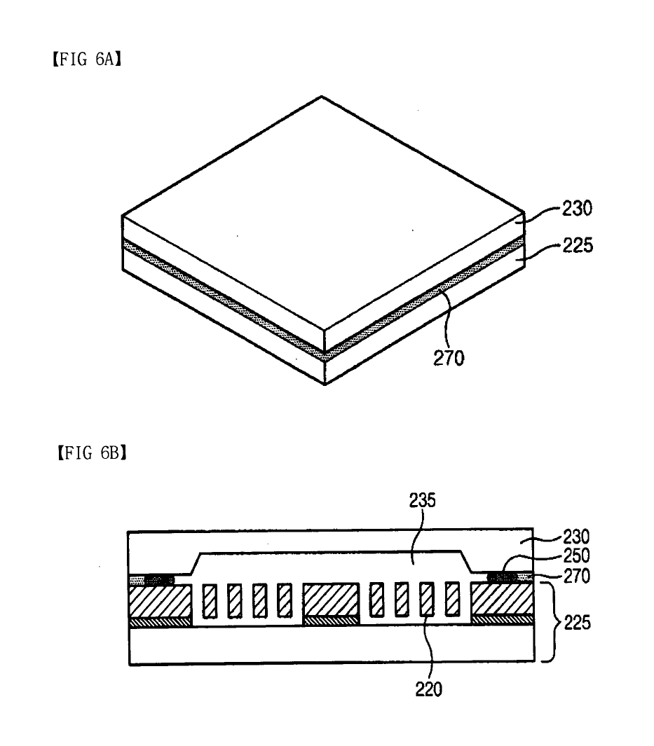

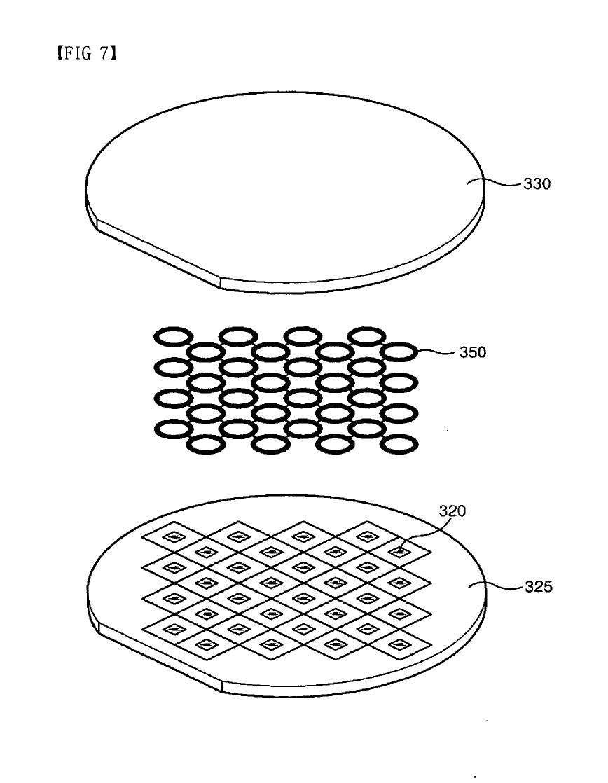

Referring to FIGS. 6A and 6B, while the upper and lower substrates 230 and 225 are being compressed by interposing the O-ring 250, the vacuum chamber is vented to an atmospheric pressure. Once the vacuum chamber is under the atmospheric pressure, the upper and lower substrates 230 and 225 are closed bonded to each other due to the atmospheric pressure.

Thereafter, the pressure applied between the upper and lower substrates 230 and 225 by the pressurizing plate 260 is removed. At this time, the upper and lower substrates 230 and 225 are packaged in vacuum due to a difference between vacuum inside the upper and lower substrates 230 and 225 and the atmospheric pressure outside the same.

The vacuum-packaged upper and lower substrates 230 and 225 are unloaded from the vacuum chamber. A sealant 270, such as a torr seal, can be filled outside the O-ring 250 between the upper and lower substrates 230 and 225.

In some cases, adhesion between the upper and lower substrates 230 and 225 can be reinforced by using a clamping unit (not shown), such that a high degree of vacuum is maintained.

Also, outer portions of the upper and lower substrates 230 and 225 between which the MEMS device 220 is embedded may be molded using a molding compound. In this molding process, airtightness of the MEMS device 220 can be maintained, components can be protected from surrounding conditions, such as temperature and humidity, any damage or transformation caused by mechanical oscillation and shocks can be avoided. The molding compound may be one selected from the group consisting of metals, ceramics, glass, thermosetting resins (particularly, thermosetting epoxy resins).

FIG. 7 is a perspective view illustrating a method of packaging a plurality of MEMS devices 320 in a vacuum state on a wafer level according to another embodiment of the present invention.

Referring to FIG. 7, a lower wafer 325 including the plurality of MEMS devices 320 and an upper wafer 330 including cavities corresponding to the MEMS devices 320 can be packaged in a vacuum state on a wafer level by aligning an O-ring structure including a plurality of O-rings 350 that surround the MEMS devices 320, respectively. In this case, the MEMS devices 320 may be a variety of MEMS devices, for example, a gyroscope, an accelerator, an optical switch, an RF switch, and a pressure sensor.

After being packaged in vacuum on the wafer level, the lower and upper wafers 325 and 330 may be diced into respective chips so that time can cost can be saved. Before or after the package is diced into the respective chips, a sealant, such as a torr-seal, may be filled between the lower and upper wafers 325 and 330 outside the O-ring structure.

Also, after the upper and lower wafers 330 and 325, which are diced into the respective chips and between which the MEMS devices 320 are embedded, are connected to each other by an electrical interconnection and molded using a molding compound, they can be used for a system on a package (SoP). The SoP refers to a technique of integrating a system on chip (SoC) including conventional multifunctional semiconductor devices with modules such as MEMS sensor devices, RF integrated circuits (ICs), and power devices. This SoP technique reduces the cost of development in each module and the packaging cost.

The vacuum-packaged MEMS device according to the present invention facilitates the SoP and enables easier constitutions of an SoP telemetric sensor that integrates ultra-precise MEMS sensor technology, SoC technology, and telematics.

According to the present invention, an upper substrate and a lower substrate can be easily bonded to each other, and the MEMS device can be packaged in vacuum using a simple process.

Also, a vacuum-packaged MEMS device with excellent reliability and a long life span can be manufactured so that it can resist mechanical stress, such as shock and oscillation, and environmental stress, such as temperature, humidity, and thermal shock.

Further, the MEMS device can be reliably packaged in vacuum without causing leakage or outgassing from a cavity, and a plurality of MEMS devices can be packaged in vacuum on a wafer level, thus reducing the cost and time.

Moreover, the vacuum-packaged MEMS device according to the present invention facilitates SoP techniques and enables easier constitutions of an SoP telemetric sensor that integrates ultra-precise MEMS sensor technology, SoC technology, and telematics.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A method of packaging a micro electro mechanical systems (MEMS) device in vacuum, the method comprising:
preparing an upper substrate including a cavity and a lower substrate including the MEMS device and loading the upper and lower substrates into a vacuum chamber;
aligning the lower and upper substrates by mounting an O-ring on a marginal portion of the MEMS device of the lower substrate;
compressing the O-ring between the upper and lower substrates by applying a pressure between the upper and lower substrates;
venting the vacuum chamber; and
removing the pressure applied between the upper and lower substrates.

2. The method of claim 1, wherein a sealant is filled between the upper and lower substrates outside the O-ring.

3. The method of claim 2, wherein the sealant is a torr-seal.

4. The method of claim 1, further comprising clamping outer portions of the upper and lower substrates using a clamp.

5. The method of claim 1, wherein the MEMS device is packaged using wafer-level vacuum packaging.

6. The method of claim 1, further comprising connecting the upper and lower substrates between which the MEMS device is embedded and molding the upper and lower substrates using a molding compound.

7. The method of claim 6, wherein the molding compound is formed of one selected from the group consisting of metals, ceramics, glass, and thermosetting resins.

8. The method of claim 1, wherein the MEMS device is one selected from the group consisting of a gyroscope, an accelerator, an optical switch, an RF switch, and a pressure sensor.

9. A vacuum-packaged MEMS device comprising:
an upper substrate including an MEMS device;
a lower substrate including a cavity; and
an elastic O-ring interposed between marginal portions of the upper and lower substrates.

10. The device of claim 9, further comprising a sealant filled between the upper and lower substrate outside the O-ring.

11. The device of claim 10, wherein the sealant is a torr-seal.

12. The device of claim 9, wherein a molding compound is molded outside the upper and lower substrates between which the MEMS device is embedded.

13. The device of claim 12, wherein the molding compound is formed of one selected from the group consisting of metals, ceramics, glass, and thermosetting resins.

14. The device of claim 9, wherein the MEMS device is one selected from the group consisting of a gyroscope, an accelerator, an optical switch, an RF switch, and a pressure sensor.

15. The device of claim 9, wherein the MEMS device is used for a system on a package (SoP).
